(19) United States
(12) Patent Application Publication
(10) Pub. No.: US 2026/0317227 A1
(43) Pub. Date: Oct. 15, 2026

(54) PROCESS FOR DEPOSITING A LAYER

(71) Applicant: Pilkington Group Limited, Lathom (GB)

(72) Inventors: Kelly LAMBRIGHT, Perrysburg, OH (US); David RIMMER, Prescot (GB); Gary Robert NICHOL, Culcheth (GB); Shannon JURCA, Perrysburg, OH (US); Jun NI, Maumee, OH (US)

(21) Appl. No.: 19/108,507

(22) PCT Filed: Sep. 6, 2023
(86) PCT No.: PCT/GB2023/052298

§ 371 Date: Mar. 4, 2025

Related U.S. Application Data
(60) Provisional application No. 63/403,910, filed on Sep. 6, 2022.

(51) Int. Cl. C03C 17/245; C03C 17/34

(52) U.S. Cl. CPC C03C 17/2453; C03C 17/3417; C03C 2217/211; C03C 2217/213; C03C 2217/24; C03C 2218/1525

(57) ABSTRACT

A process for manufacturing a coated glass article includes providing an aqueous solution of dimethyl tin dichloride (DMT) and vaporising the aqueous solution of dimethyl tin dichloride to form a gaseous mixture comprising dimethyl tin dichloride and water. The gaseous mixture is delivered to the surface of a glass substrate and a layer based on tin oxide is deposited on the surface of the glass substrate, the surface of the glass substrate being at a temperature of at least 550° C. when the gaseous mixture is delivered to the surface of the glass substrate.

This invention relates to a process for depositing a layer on a surface of a substrate.

Coatings on substrate surfaces find uses in many fields. Some of the more useful coatings are metal oxides, for example, tin oxide. Some metal oxides (including doped tin oxide) can form transparent conductive oxide (TCO) coatings.

Methods used to deposit metal oxide coatings include physical vapour deposition methods, such as sputtering, or liquid based methods, such as sol-gel using spin-coating or dip-coating techniques, among others. One particularly useful method for deposition of coatings is chemical vapour deposition (CVD) wherein a fluid precursor in the form of a vapour is delivered to the surface of the substrate where the precursors react and/or decompose thereby depositing a coating. Different subsets of CVD include metal organic (MO) CVD, combustion (C) CVD, plasma enhanced (PE) CVD and aerosol-assisted (AA) CVD.

An important aspect of successful CVD processes is the choice of precursor. In the case of tin oxide coatings, a number of metal precursors have been investigated. Dimethyl tin dichloride (DMT) has been utilised extensively as a precursor for the deposition of tin oxide coatings for over thirty years. For instance, in U.S. Pat. No. 5,090,985A DMT was heated to a liquid, combined with nitrogen, vaporised, mixed with oxygen and water vapour, and directed onto the surface of a hot glass substrate as it is being manufactured by the float glass process.

DMT is generally supplied as a solid material which requires specialised containers, making transport and storage difficult. It would be beneficial to afford greater versatility in how DMT can be used as a precursor for tin oxide coatings, and consequently how it may be transported and stored.

According to a first aspect of the present invention there is provided a process for manufacturing a coated glass article,
said process comprising:
providing a glass substrate having a surface,
providing an aqueous solution of dimethyl tin dichloride (DMT),
vaporising the aqueous solution of dimethyl tin dichloride to form a gaseous mixture comprising dimethyl tin dichloride and water,
delivering the gaseous mixture to the surface of the glass substrate, and
depositing a layer based on tin oxide on the surface of the glass substrate,
wherein the surface of the glass substrate is at a temperature of at least 550° C. when the gaseous mixture is delivered to said surface of the glass substrate.

It has surprisingly been found that an aqueous solution of DMT can be used directly in order to deposit tin oxide on a glass substrate at the above temperatures. This provides a useful alternative to the conventional approach of vaporising DMT and then combining with water vapour.

In the context of the present invention, where a layer is said to be “based on” a particular material or materials, this means that the layer predominantly consists of the corresponding said material or materials, which means typically that it comprises at least about 50 at. % of said material or materials.

In the following discussion of the invention, unless stated to the contrary, the disclosure of alternative values for the upper or lower limit of the permitted range of a parameter, coupled with an indication that one of said values is more highly preferred than the other, is to be construed as an implied statement that each intermediate value of said parameter, lying between the more preferred and the less preferred of said alternatives, is itself preferred to said less preferred value and also to each value lying between said less preferred value and said intermediate value.

Throughout this specification, the term “comprising” or “comprises” means including the component(s) specified but not to the exclusion of the presence of other components. The term “consisting essentially of” or “consists essentially of” means including the components specified but excluding other components except for materials present as impurities, unavoidable materials present as a result of processes used to provide the components, and components added for a purpose other than achieving the technical effect of the invention. Typically, when referring to compositions, a composition consisting essentially of a set of components will comprise less than 5% by weight, typically less than 3% by weight, more typically less than 1% by weight of non-specified components.

The term “consisting of” or “consists of” means including the components specified but excluding other components.

Whenever appropriate, depending upon the context, the use of the term “comprises” or “comprising” may also be taken to include the meaning “consists essentially of” or “consisting essentially of”, and also may also be taken to include the meaning “consists of” or “consisting of”.

References herein such as “in the range x to y” are meant to include the interpretation “from x to y” and so include the values x and y.

In the context of the present invention a transparent material or a transparent substrate is a material or a substrate that is capable of transmitting visible light so that objects or images situated beyond or behind said material can be distinctly seen through said material or substrate.

In the context of the present invention the “thickness” of a layer is, for any given location at a surface of the layer, represented by the distance through the layer, in the direction of the smallest dimension of the layer, from said location at a surface of the layer to a location at an opposing surface of said layer.

In the context of the present invention a “derivative” is a chemical substance related structurally to another chemical substance and theoretically derivable from it.

When the gaseous mixture is delivered to said surface of the glass substrate, preferably the surface of the glass substrate is at a temperature of at least 570° C., more preferably at least 580° C., even more preferably at least 590° C., most preferably at least 600° C., but preferably at most 800° C., more preferably at most 750° C., even more preferably at most 730° C., most preferably at most 720° C. In some preferred embodiments, when the gaseous mixture is delivered to said surface of the glass substrate, the surface of the glass substrate is at a temperature of at least 580° C. but at most 750° C. Depositing a layer when the substrate is at these preferred temperatures affords greater crystallinity of the layer, which can improve toughenability (resistance to heat treatment).

Preferably the coated glass article exhibits a sheet resistance of at most 50 ohm/sq, more preferably at most 40 ohm/sq, even more preferably at most 30 ohm/sq, most preferably at most 25 ohm/sq, but preferably at least 1 ohm/sq, more preferably at least 3 ohm/sq, even more preferably at least 5 ohm/sq. In alternative embodiments the coated glass article may exhibit a sheet resistance of 40 to 350 ohm/sq, preferably 40 to 325 ohm/sq, or the coated glass article may exhibit a sheet resistance of 1000 to 3000 ohm/sq. The sheet resistance exhibited by the coated glass article is measured on the surface of the glass substrate upon which the layer based on tin oxide has been deposited. The sheet resistance exhibited by the coated glass article can be measured using a 4-point probe method and a commercially available 4-point probe.

Preferably the gaseous mixture also comprises molecular oxygen and/or a carrier gas. More preferably the gaseous mixture also comprises molecular oxygen and a carrier gas. Molecular oxygen can be provided as a part of a gaseous composition such as air or in a substantially purified form. Preferably the carrier gas comprises nitrogen, argon and/or helium. Regardless of the specific constituents, since the gaseous mixture is comprised of more than one gas, the gases are preferably premixed so that the gaseous mixture is substantially uniform prior to depositing the layer based on tin oxide.

Preferably the aqueous solution of dimethyl tin dichloride has a concentration of at least 30% wt, more preferably at least 40% wt, even more preferably at least 45% wt, but preferably at most 70% wt, more preferably at most 60% wt, even more preferably at most 55% wt.

Preferably the gaseous mixture has a molar percentage of DMT of at least 0.5 mol %, more preferably at least 1 mol %, even more preferably at least 1.5 mol %, but preferably at most 10 mol %, more preferably at most 7 mol %, even more preferably at most 5 mol %.

Preferably the gaseous mixture has a molar percentage of water of at least 15 mol %, more preferably at least 25 mol %, even more preferably at least 30 mol %, but preferably at most 60 mol %, more preferably at most 50 mol %, even more preferably at most 40 mol %. In some preferred embodiments the gaseous mixture further comprises water added separately in addition to the water formed by vaporising the aqueous solution of DMT.

Preferably the gaseous mixture has a molar percentage of oxygen of at least 15 mol %, more preferably at least 25 mol %, even more preferably at least 30 mol %, but preferably at most 50 mol %, more preferably at most 40 mol %, even more preferably at most 35 mol %.

Preferably said surface of the glass substrate is a major surface of the glass substrate. Preferably the glass substrate is transparent. The glass substrate may be a clear metal oxide-based glass pane. Preferably the glass pane is a clear float glass pane, preferably a low iron float glass pane. By clear float glass, it is meant a glass having a composition as defined in BS EN 572-1 and BS EN 572-2 (2004). For clear float glass, the Fe₂O₃ level by weight is typically 0.11%. Float glass with an Fe₂O₃ content less than about 0.05% by weight is typically referred to as low iron float glass. Such glass usually has the same basic composition of the other component oxides i.e. low iron float glass is also a soda-lime-silicate glass, as is clear float glass. Typically, low iron float glass has less than 0.02% by weight Fe₂O₃. Alternatively, the glass pane is a borosilicate-based glass pane, an alkali-aluminosilicate-based glass pane, or an aluminium oxide-based crystal glass pane.

Preferably, the formation of the gaseous mixture comprises heating the aqueous solution of dimethyl tin dichloride and/or any further precursor compound. Preferably said heating uses a bubbler system or a thin film evaporator system. Thin film evaporator systems are particularly suited to production scale processes.

Preferably the aqueous solution of dimethyl tin dichloride is heated to a temperature of at least 160° C., more preferably at least 170° C., even more preferably at least 175° C., but preferably at most 240° C., more preferably at most 220° C., even more preferably at most 210° C.

Preferably the gaseous mixture reaches a vapour pressure of at least 0.01 Bar, more preferably at least 0.03 Bar, even more preferably at least 0.04 Bar, most preferably at least 0.05 Bar.

Preferably the process is carried out using Chemical Vapour Deposition (CVD). The CVD may be carried out in conjunction with the manufacture of the substrate, preferably a transparent glass substrate. In an embodiment, the glass substrate may be formed utilizing the well-known float glass manufacturing process. Preferably the process is carried out during the float glass manufacturing process. In this embodiment, the glass substrate may also be referred to as a glass ribbon. Conveniently, the CVD may be carried out either in the float bath, in the lehr or in the lehr gap. The preferred method of CVD is atmospheric pressure CVD (e.g. online CVD as performed during the float glass process). However, it should be appreciated that the CVD process can be utilised apart from the float glass manufacturing process or well after formation and cutting of the glass ribbon.

As detailed above, preferably the CVD may be carried out during the float glass production process at substantially atmospheric pressure. Alternatively, the CVD may be carried out using low-pressure CVD or ultrahigh vacuum CVD. The CVD may be carried out using aerosol assisted CVD or direct liquid injection CVD. Furthermore, the CVD may be carried out using microwave plasma-assisted CVD, plasma-enhanced CVD, remote plasma-enhanced CVD, atomic layer CVD, combustion CVD (flame pyrolysis), hot wire CVD, metalorganic CVD, rapid thermal CVD, vapour phase epitaxy, or photo-initiated CVD. The glass substrate will usually be cut into sheets after deposition of any CVD layer(s) for storage or convenient transport.

In certain embodiments, the CVD is a dynamic deposition process. Thus, in these embodiments, the glass substrate is moving at the time of forming the layer based on tin oxide thereon or thereover. Preferably, the glass substrate moves at a predetermined rate of, for example, greater than 1.78 m/min (70 in/min), more preferably greater than 2.5 m/min (98.4 in/min), as the layer based on tin oxide is being deposited. In an embodiment, the glass substrate is moving at a rate of between 3.175 m/min (125 in/min) and 16.7 m/min (657 in/min), preferably between 3.175 m/min (125 in/min) and 15.24 m/min (600 in/min), as the layer based on tin oxide is being deposited.

Where the process is carried out during the float glass manufacturing process, a float glass apparatus may be provided, which preferably comprises a canal section along which molten glass is delivered from a melting furnace, to a float bath section wherein a continuous glass ribbon is formed by the process. The glass ribbon may advance from the bath section through an adjacent annealing lehr and a cooling section. The continuous glass ribbon may serve as the substrate upon which the layer based on tin oxide is deposited.

The bath section may include a bottom section within which a bath of molten tin is contained, a roof, opposite sidewalls, and end walls. It is understood that the bath may include other suitable materials to achieve the desired results. The roof, side walls, and end walls together may define an enclosure in which a non-oxidizing atmosphere is maintained to prevent oxidation of the molten tin. Additionally, a coating apparatus comprising gas distributor beams may be located in the bath section. Gas distributor beams in the bath section may be employed to apply the layer based on tin oxide by the process of the presently described subject matter or additional coatings onto the substrate prior to, or after, applying the layer based on tin oxide.

In operation, the molten glass may flow along the canal beneath a regulating tweel and downwardly onto the surface of the tin bath in controlled amounts. On the tin bath the molten glass spreads laterally under the influences of gravity and surface tension, as well as certain mechanical influences, and it is advanced across the bath to form the ribbon. The ribbon may be removed over lift out rolls and is preferably thereafter conveyed through an annealing lehr and a cooling section on aligned rolls. Heaters may be provided within the annealing lehr for causing the temperature of the glass ribbon to be gradually reduced in accordance with a predetermined regime as it is conveyed therethrough. Also, typically ambient air may be directed against the glass ribbon via fans in the cooling section.

The process of the presently described subject matter may take place in the float bath section or further along the production line. For example, the layer based on tin oxide may be deposited in a gap between the float bath section and the annealing lehr or in the annealing lehr itself.

For carrying out the process in the float bath section, a suitable non-oxidizing atmosphere, generally nitrogen or a mixture of nitrogen and hydrogen in which nitrogen predominates, may be maintained to prevent oxidation of the molten tin. The atmosphere gas may be admitted through conduits operably coupled to a distribution manifold. The non-oxidizing atmosphere gas may be introduced at a rate sufficient to compensate for normal losses and maintain a slight positive pressure, on the order of about 0.001 to about 0.01 atmospheres above ambient atmospheric pressure, so as to prevent infiltration of outside atmosphere. For purposes of the presently described subject matter the above-noted pressure range is considered to constitute normal atmospheric pressure. Heat for maintaining the desired temperature regime in the tin bath and the enclosure may be provided by radiant heaters within the enclosure and the glass ribbon itself.

The atmosphere within the lehr is typically atmospheric air. However, an inert atmosphere may be maintained in the lehr section if so desired. Similarly, the atmosphere in the gap between the lehr and the bath is typically atmospheric air and the bath section atmosphere, however an inert atmosphere may be provided. In either scenario, the pressure of the inert atmosphere may be substantially similar to the pressure of the bath section atmosphere.

Gas distributor beams may be positioned in the bath section, the gap between the bath section and the annealing lehr, or in the annealing lehr to deposit the layer based on tin oxide on the glass ribbon substrate. The gas distributor beam is one form of reactor that can be employed in practicing the process of the presently described subject matter.

A configuration for the distributor beams suitable for supplying precursor materials in accordance with the presently described subject matter is an inverted, generally channel-shaped framework formed by spaced inner and outer walls and defining two enclosed cavities. A suitable heat exchange medium may be circulated through the enclosed cavities in order to maintain the distributor beams at a desired temperature.

Preferably, the gaseous mixture is delivered to the coating apparatus. In certain embodiments, the gaseous mixture is fed through a coating apparatus and discharged from the coating apparatus utilizing one or more gas distributor beams prior to deposition of the layer based on tin oxide. Preferably, the gaseous mixture is formed prior to being fed through the coating apparatus. For example, the aqueous solution of dimethyl tin dichloride may be vaporised and delivered to a feed line connected to an inlet of the coating apparatus. Molecular oxygen and/or a carrier gas such as nitrogen may be delivered to the feed line and mixed with the DMT and water. In other embodiments, the gaseous mixture may be formed within the coating apparatus.

The gaseous mixture may be supplied through a supply conduit. Depending on the location of the deposition, the supply conduit may be surrounded by a cooling fluid. The supply conduit may extend along the distributor beam and admit the gaseous mixture through drop lines spaced along the supply conduit. The supply conduit may lead to a delivery chamber within a header carried by the framework. The gaseous mixture admitted through the drop lines may be discharged from the delivery chamber through a passageway toward a coating chamber defining a vapor space opening onto the glass substrate where the gaseous mixture flows along the surface of the substrate.

Baffle plates may be provided within the delivery chamber for equalizing the flow of the gaseous mixture across the distributor beam to assure that the gaseous mixture is discharged against the glass substrate in a smooth, laminar, uniform flow entirely across the distributor beam. Spent precursor gases may be collected and removed through exhaust chambers along the sides of the distributor beam.

Various forms of distributor beams used for chemical vapor deposition are suitable for the present method and are known in the prior art. In one such alternative distributor beam configuration, the gaseous mixture is introduced through a gas supply duct where it is cooled by cooling fluid circulated through a plurality of ducts. The gas supply duct may open through an elongated aperture into a glass flow restrictor.

The gas flow restrictor may comprise a plurality of metal strips longitudinally crimped in the form of a sine wave and vertically mounted in abutting relationship with one another extending along the length of the distributor. Adjacent crimped metal strips may be arranged “out of phase” to define a plurality of vertical channels between them. These vertical channels may be of small cross-sectional area relative to the cross-sectional area of the gas supply duct, so that the gaseous mixture is released from the gas flow restrictor at substantially constant pressure along the length of the distributor.

The gaseous mixture may be released from the gas flow restrictor into the inlet side of a substantially U-shaped guide channel generally comprising an inlet leg of a coating chamber which opens onto the glass substrate, and at least one exhaust leg, whereby used precursor gases are withdrawn from the glass. It is understood that the guide channel may have any suitable size, shape, and configuration as desired. The rounded corners of the blocks defining the coating channel promote a uniform laminar flow of coating parallel to the glass substrate surface.

Preferably the layer based on tin oxide is deposited on the surface of the glass substrate at a deposition rate of at least 2 nm per second, more preferably at least 5 nm per second, even more preferably at least 7 nm per second.

Preferably the layer based on tin oxide comprises, more preferably consists essentially of, even more preferably consists of, tin (IV) oxide.

In some preferred embodiments the layer based on tin oxide may comprise doped tin oxide and/or may comprise a mixed oxide. The doped tin oxide may be doped with one or more of fluorine, indium, antimony, boron, manganese, zinc, aluminium, chromium, phosphorus, strontium or cadmium. Preferably the doped tin oxide is doped with one or more of fluorine, indium or antimony. More preferably the doped tin oxide is doped with fluorine. In this case, preferably the gaseous mixture also comprises HF and/or tri-fluoro acetic acid. Doping the layer based on tin oxide can enable said layer to become electrically conductive.

When doped, preferably the layer based on tin oxide comprises at least 0.2 atomic % dopant, more preferably at least 0.4 atomic % dopant, even more preferably at least 0.6 atomic % dopant, most preferably at least 0.8 atomic % dopant, but preferably at most 5 atomic % dopant, more preferably at most 2 atomic % dopant, even more preferably at most 1.5 atomic % dopant, most preferably at most 1.2 atomic % dopant. These preferred ranges can provide advantages for solar cell applications in terms of optimising cell efficiency.

The layer based on tin oxide may be deposited directly on the surface of the glass substrate. Alternatively, said layer based on tin oxide may be deposited indirectly on the surface of the glass substrate i.e. said layer based on tin oxide may be deposited over one or more previously deposited layers. For example, said layer based on tin oxide may be deposited over, and preferably directly contacts, a layer based on silica. In some preferred embodiments, said layer based on tin oxide is deposited over, and directly contacts, a layer based on silica, wherein said layer based on silica has been deposited over, and directly contacts, a further layer based on tin oxide.

Where the process is carried out during the float glass manufacturing process, preferably said surface of the glass substrate is the gas side surface. Coated glass manufacturers usually prefer depositing coatings on the gas side surface (as opposed to the tin side surface for float glass) because deposition on the gas side surface can improve the properties of the coating.

Also, the coated glass article may exhibit a low haze value. As discussed herein, the term “haze” refers to the percentage of incident visible light that scatters when passing through the coated glass article. Also, as discussed herein, the haze exhibited by the coated glass article is measured from the surface of the glass substrate upon which the layer based on tin oxide has been deposited. In an embodiment, the coated glass article may exhibit haze of 0.5% or less. Preferably, the coated glass article exhibits a haze of 0.4% or less. In some embodiments, the haze exhibited by the coated glass article is 0.1-0.4%. The haze exhibited by the coated glass article can be measured using a commercially available haze meter such as the BYK-Gardner haze-gard plus.

Any invention described herein may be combined with any feature of any other invention described herein mutatis mutandis.

It will be appreciated that optional features applicable to one aspect of the invention can be used in any combination, and in any number. Moreover, they can also be used with any of the other aspects of the invention in any combination and in any number. This includes, but is not limited to, the dependent claims from any claim being used as dependent claims for any other claim in the claims of this application.

The reader's attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention will now be further described by way of the following specific embodiments, which are given by way of illustration and not of limitation, with reference to the accompanying drawings in which:

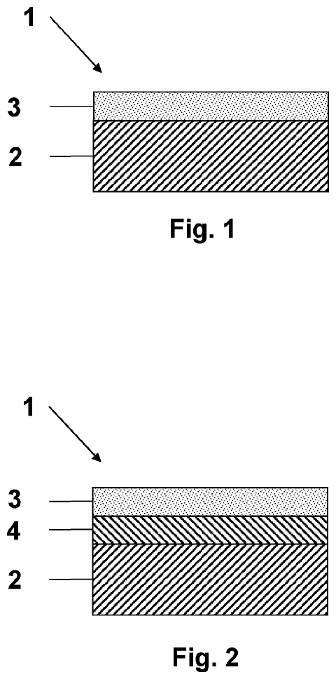

FIG. 1 is a schematic view, in cross-section, of a coated glass article in accordance with certain embodiments of the present invention;

FIG. 2 is a schematic view, in cross-section, of a coated glass article in accordance with certain embodiments of the present invention;

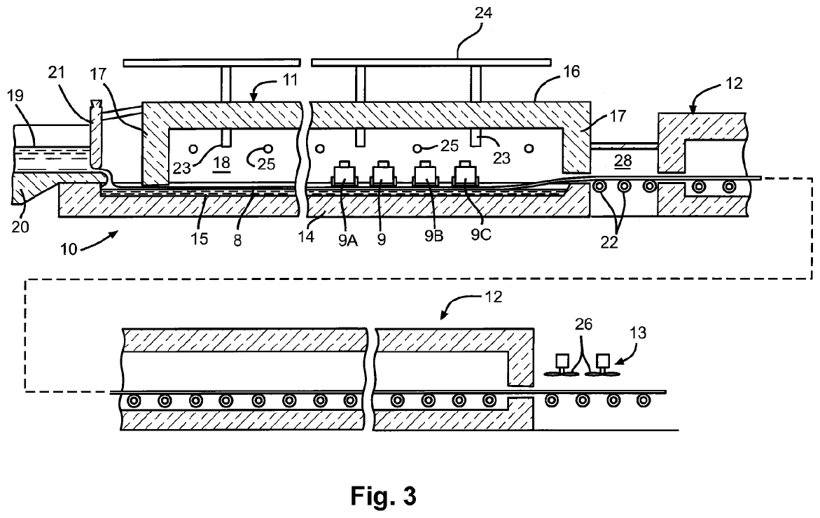

FIG. 3 is a schematic view, in vertical section, of an installation for practicing the float glass process which incorporates several CVD apparatuses for manufacturing a coated glass article in accordance with certain embodiments of the present invention.

FIG. 1 shows a cross-section of a coated glass article 1 according to certain embodiments of the present invention. Coated glass article 1 comprises a transparent float glass substrate 2 that has been coated using CVD with a layer based on tin oxide 3.

FIG. 2 shows a cross-section of a coated glass article 1 according to certain embodiments of the present invention. Coated glass article 1 comprises a transparent float glass substrate 2 that has been sequentially coated using CVD with a layer based on silica 4 and a layer based on tin oxide 3.

As discussed above, the process of the present invention may be carried out using CVD in conjunction with the manufacture of the glass substrate in the float glass process. The float glass process is typically carried out utilizing a float glass installation such as the installation 10 depicted in FIG. 3. However, it should be understood that the float glass installation 10 described herein is only illustrative of such installations.

As illustrated in FIG. 3, the float glass installation 10 may comprise a canal section 20 along which molten glass 19 is delivered from a melting furnace, to a float bath section 11 wherein the glass substrate is formed. In this embodiment, the glass substrate will be referred to as a glass ribbon 8. However, it should be appreciated that the glass substrate is not limited to being a glass ribbon. The glass ribbon 8 advances from the bath section 11 through an adjacent annealing lehr 12 and a cooling section 13. The float bath section 11 includes: a bottom section 14 within which a bath of molten tin 15 is contained, a roof 16, opposite side walls (not depicted) and end walls 17. The roof 16, side walls and end walls 17 together define an enclosure 18 in which a non-oxidizing atmosphere is maintained to prevent oxidation of the molten tin 15.

In operation, the molten glass 19 flows along the canal 20 beneath a regulating tweel 21 and downwardly onto the surface of the tin bath 15 in controlled amounts. On the molten tin surface, the molten glass 19 spreads laterally under the influence of gravity and surface tension, as well as certain mechanical influences, and it is advanced across the tin bath 15 to form the glass ribbon 8. The glass ribbon 8 is removed from the bath section 11 over lift out rolls 22 and is thereafter conveyed through the annealing lehr 12 and the cooling section 13 on aligned rolls. The deposition of coatings preferably takes place in the float bath section 11, although it may be possible for deposition to take place further along the glass production line, for example, in the gap 28 between the float bath 11 and the annealing lehr 12, or in the annealing lehr 12.

As illustrated in FIG. 3, four CVD apparatuses 9, 9A, 9B, 9C are shown within the float bath section 11. Thus, depending on the frequency and thickness of the coating layers required it may be desirable to use some or all of the CVD apparatuses 9, 9A, 9B, 9C. One or more additional coating apparatuses (not depicted) may be provided. One or more CVD apparatus may alternatively or additionally be located in the lehr gap 28. Any by-products are removed through coater extraction slots and then through a pollution control plant. For example, in an embodiment, a silica layer is formed utilizing using CVD apparatus 9A and a fluorine doped tin oxide layer is formed utilizing CVD apparatus 9.

A suitable non-oxidizing atmosphere, generally nitrogen or a mixture of nitrogen and hydrogen in which nitrogen predominates, may be maintained in the float bath section 11 to prevent oxidation of the molten tin 15 comprising the float bath. The atmosphere gas is admitted through conduits 23 operably coupled to a distribution manifold 24. The non-oxidizing gas is introduced at a rate sufficient to compensate for normal losses and maintain a slight positive pressure, on the order of between about 0.001 and about 0.01 atmosphere above ambient atmospheric pressure, so as to prevent infiltration of outside atmosphere. For the purposes of describing the invention, the above-noted pressure range is considered to constitute normal atmospheric pressure.

CVD is generally performed at essentially atmospheric pressure. Thus, the pressure of the float bath section 11, annealing lehr 12, and/or in the gap 28 between the float bath 11 and the annealing lehr 12 may be essentially atmospheric pressure. Heat for maintaining the desired temperature regime in the float bath section 11 and the enclosure 18 is provided by radiant heaters 25 within the enclosure 18. The atmosphere within the lehr 12 is typically atmospheric air, as the cooling section 13 is not enclosed and the glass ribbon 8 is therefore open to the ambient atmosphere. The glass ribbon 8 is subsequently allowed to cool to ambient temperature. To cool the glass ribbon 8, ambient air may be directed against the glass ribbon 8 by fans 26 in the cooling section 13. Heaters (not shown) may also be provided within the annealing lehr 12 for causing the temperature of the glass ribbon 8 to be gradually reduced in accordance with a predetermined regime as it is conveyed therethrough.

### EXAMPLES

The chemical components aqueous DMT (50%. wt/wt, Galata), nitrogen (compressed liquid, Air Products), oxygen (PT #Ox ED300, extra dry, AirGas), were used as received without further purification.

Aqueous DMT was used directly as the precursor for atmospheric pressure chemical vapor deposition of SnO₂ thin films on SiO₂ coated low-iron soda-lime float glass plates (2.8 mm×20.3 cm×61.0 cm, “the substrate”) using an on-line mini dynamic coater. The substrate was mounted onto an electronically controlled ceramic conveyer “boat” that moved through the components of the coating furnace. First the substrate paused in the pre-heat section until it reached 620° C. and then moved into the main furnace which is maintained at the same temperature. Once in the main furnace, the substrate either moved at a line speed of 190.5 cm/min (preferably 63.5 to 889 cm/min, more preferably 190.5 to 508 cm/min) or was stationary for 15 or 20 seconds while the gaseous mixture exited a 15.2 cm precursor nozzle, thus depositing a dynamic or static coating, respectively. For the examples herein a dynamic coating was prepared. From the main furnace the coated glass article moved into the annealing section, where it remained until it decreased to a set temperature (400° C.) and then exited the furnace to be fan cooled.

The gaseous mixture was prepared as follows: Nitrogen carrier gas was piped through to a stainless steel (316 steel) pressure pot that was used as for aqueous dimethyltin dichloride containment and delivery. Using a sapphire rotameter, aqueous dimethyltin dichloride was metered into a tube evaporator set to 350° F. (176.7° C.). Additional nitrogen gas was flowed through the barrel of the evaporator to carry the dimethyltin dichloride and water vapors to the coater head via heated lines (200-220° C.) and a 4-way connector in a 200° C. oven. Oxygen gas was combined with the DMT, water and nitrogen vapors just before the 4-way connector. After each deposition water from a metered pressure pot was used to purge the system.

Examples were prepared using five different sets of conditions, as shown below in Table 1, such that the proportions of DMT and water in the gaseous mixture were varied. Each example was prepared on three different occasions and average measurements of thickness and efficiency were determined. Table 1 shows the proportions of each component in the gaseous mixture, with nitrogen making up the balance. Table 1 also shows the flow rates for each component, average thickness of the deposited tin oxide layers and average deposition efficiency. The deposition efficiency is essentially the percentage of the moles of DMT in the gaseous mixture that actually deposit onto the substrate as tin oxide per minute. The area coated is defined by the width of the glass and its line speed.

TABLE 1
deposition conditions and resultant coating thicknesses and deposition
efficiencies for several Examples according to the present invention

| | | | | | | | | Average |
|---|---|---|---|---|---|---|---|---|
| | | | | | | Balance | Average | Deposition |
| | DMT | H₂O | O₂ | aq-DMT | O₂ | N₂ | thickness | Efficiency |
| | (mol %) | (mol %) | (mol %) | (cc/min) | (SLPM) | (SLPM) | (nm) | (%) |
| Example 1 | 1.50 | 18.3 | 30.0 | 5.9 | 7.2 | 11.81 | 108 | 10.8 |
| Example 2 | 1.75 | 21.4 | 30.0 | 6.9 | 7.2 | 10.98 | 130 | 11.7 |
| Example 3 | 2.00 | 24.4 | 30.0 | 7.8 | 7.2 | 10.15 | 159 | 12.5 |
| Example 4 | 2.25 | 27.5 | 30.0 | 8.8 | 7.2 | 9.31 | 168 | 10.5 |
| Example 5 | 2.50 | 30.5 | 30.0 | 9.8 | 7.2 | 8.48 | 190 | 12.7 |

The results shown in Table 1 demonstrate that the thickness of the tin oxide layer increases with an increased proportion of DMT and water in the gaseous mixture. In addition, all the Examples demonstrate reasonable deposition efficiency.

The invention is not restricted to the details of the foregoing embodiments. The invention extends to any novel one, or any novel combination, of the features disclosed in this specification (including any accompanying claims, abstract and drawings), or to any novel one, or any novel combination, of the steps of any method or process so disclosed.

1.-18. (canceled)

19. A process for manufacturing a coated glass article, said process comprising:
providing a glass substrate having a surface,
providing an aqueous solution of dimethyl tin dichloride (DMT),
vaporising the aqueous solution of dimethyl tin dichloride to form a gaseous mixture comprising dimethyl tin dichloride and water,
delivering the gaseous mixture to the surface of the glass substrate, and
depositing a layer based on tin oxide on the surface of the glass substrate,
wherein the surface of the glass substrate is at a temperature of at least 550° C. when the gaseous mixture is delivered to said surface of the glass substrate.

20. The process according to claim 19, wherein when the gaseous mixture is delivered to said surface of the glass substrate, the surface of the glass substrate is at a temperature of at least 570° C.

21. The process according to claim 19, wherein when the gaseous mixture is delivered to said surface of the glass substrate, the surface of the glass substrate is at a temperature of at least 580° C. but at most 750° C.

22. The process according to claim 19, wherein the coated glass article exhibits a sheet resistance of at most 50 ohm/sq.

23. The process according to claim 19, wherein the gaseous mixture also comprises molecular oxygen and/or a carrier gas.

24. The process according to claim 19, wherein the aqueous solution of dimethyl tin dichloride has a concentration of at least 30% wt.

25. The process according to claim 19, wherein the gaseous mixture has a molar percentage of DMT of at least 0.5 mol %.

26. The process according to claim 19, wherein the gaseous mixture has a molar percentage of water of at least 15 mol %.

27. The process according to claim 19, wherein the gaseous mixture has a molar percentage of oxygen of at least 15 mol %.

28. The process according to claim 19, wherein the formation of the gaseous mixture comprises heating the aqueous solution of dimethyl tin dichloride and/or any further precursor compound, optionally wherein said heating uses a bubbler system or a thin film evaporator system.

29. The process according to claim 28, wherein the aqueous solution of dimethyl tin dichloride is heated to a temperature of at least 160° C.

30. The process according to claim 19, wherein the process is carried out using Chemical Vapour Deposition (CVD).

31. The process according to claim 19, wherein the process is carried out during the float glass manufacturing process.

32. The process according to claim 19, wherein the layer based on tin oxide comprises doped tin oxide and/or comprises a mixed oxide.

33. The process according to claim 32, wherein the doped tin oxide is doped with one or more of fluorine, indium, antimony, boron, manganese, zinc, aluminium, chromium, phosphorus, strontium or cadmium.

34. The process according to claim 19, wherein said layer based on tin oxide is deposited directly on the surface of the glass substrate.

35. The process according to claim 19, wherein said layer based on tin oxide is deposited indirectly on the surface of the glass substrate and wherein said layer based on tin oxide is deposited over, and optionally contacts, a layer based on silica.

36. The process according to claim 35, wherein said layer based on silica has been deposited over, and directly contacts, a further layer based on tin oxide.
